(19) United States
(12) Patent Application Publication
(10) Pub. No.: US 2016/0286678 A1
(43) Pub. Date: Sep. 29, 2016

(54) HOUSING FOR EXPANSION CARDS

(71) Applicant: HEWLETT PACKARD ENTERPRISE DEVELOPMENT LP, Houston, TX (US)

(72) Inventors: Raghavan V Venugopal, Spring, TX (US); Chin-Lung Chiang, Taipei (TW); Patrick A Raymond, Houston, TX (US); Chih-Chiang Chen, Taipei (TW)

(21) Appl. No.: 15/033,626

(22) PCT Filed: Jan. 31, 2014
(86) PCT No.: PCT/US2014/014035

§ 371 Date: Apr. 30, 2016

(51) Int. Cl. H05K 7/14; G06F 13/40

(52) U.S. Cl. CPC H05K 7/1439; G06F 13/4068; G06F 13/409

(57) ABSTRACT

Devices and methods for engagement of an expansion card (312) with an expansion slot (104) of a printed circuit board (PCB) based connector (102) are described. In one example, an expansion card module (300) includes a card housing (302) to house an expansion card (312). The card housing (302) includes a groove (304) for engaging the card housing (302) with a locking element (202) of a device case housing (200) to mount the expansion card module (300) in the device case housing (200). The expansion card module (300) also includes a module mounted actuator (306) pivotally mounted on the card housing (302) to engage with the locking element (202) for actuating the expansion card module (300) to engage the expansion card (312) with at least one expansion slot (104) of the PCB based connector (102).

### BACKGROUND

A computing device, such as a desktop computer, a server and a workstation, typically includes a case which encloses device components, such as processors, memory chips, peripheral interface devices, and other circuit elements. The case is used for holding the device components together and for keeping the components safe from factors, such as dust and moisture. A printed circuit board, such as a motherboard can also be mounted within the case that houses the components of the computing device. The motherboard may include a number expansion slots. An expansion slot is a slit-like socket into which an expansion card can be inserted. Many types of expansion cards can be inserted into the expansion slots for adding more memory, graphics capabilities, and other capabilities and functions to the computing device without altering the structure of the computing device. Examples of the expansion cards include sound cards, video cards, interface cards, memory cards, and graphics cards.

### BRIEF DESCRIPTION OF DRAWINGS

The detailed description is described with reference to the accompanying figures. In the figures, the left-most digit(s) of a reference number identifies the figure in which the reference number first appears. The same numbers are used throughout the figures to reference like features and components:

FIG. 1a illustrates a perspective view of a housing case fora printed circuit board (PCB) based connector, according to an example of the present subject matter.

FIG. 1b illustrates an inner top view of the housing case for the PCB based connector, according to an example of the present subject matter.

FIG. 2a illustrates a perspective view of a device case housing for the PCB based connector, according to an example of the present subject matter.

FIG. 2b illustrates an inner top view of the device case housing for the PCB based connector, according to an example of the present subject matter.

FIG. 3a illustrates a perspective view of an expansion card module for engagement of an expansion card with the PCB based connector, according to an example of the present subject matter.

FIG. 3b illustrates a perspective view of the expansion card module housing the expansion card, according to an example of the present subject matter.

FIG. 3c illustrates an inner top view of the expansion card module, according to an example of the present subject matter.

FIG. 3d illustrates an inner top view of the expansion card module having the expansion card, according to an example of the present subject matter.

FIGS. 3e and 3f illustrate the expansion card module, according to other example of the present subject matter.

FIGS. 4a 4b, 4c, and 4d illustrate the expansion card module inserted into the housing case for engagement of the expansion card with an expansion slot of the PCB based connector, according to an example of the present subject matter.

FIGS. 5a 5b, 5c, and 5d illustrate the expansion card module removed from the housing case for disengagement of the expansion card from the expansion slot of the PCB based connector, according to an example of the present subject matter.

FIGS. 6a, 6b, 6c, 6d, and 6e illustrate the expansion card module inserted into the device case housing for engagement of the expansion card with the expansion slot of the PCB based connector, according to an example of the present subject matter.

FIGS. 7a, 7b, 7c, 7d, and 7e illustrate the expansion card module removed from the device case housing for disengagement of the expansion card from the expansion slot of the PCB based connector, according to an example of the present subject matter.

### DETAILED DESCRIPTION

In recent years, in order to impart more functionalities to computing devices for fulfilling various requirements of users, different kinds of function-adding expansion cards have been developed. These expansion cards electrically connect to a computing device through standardized expansion slots on the motherboard of the computing device and extend the functionalities and capabilities of the computing device. Further, as new technologies develop, computing devices have become lighter and more compact, and consequently the cases housing the components of the computing devices are smaller.

Since the expansion cards come in many different standards and sizes, for some of the expansion cards, owing to the compact size of the cases, the dimension of the cases may not allow for a perpendicular placement of the expansion cards into the motherboard. In other words, the length of the expansion cards may be such that it may not be feasible to accommodate the expansion cards in the motherboard along the length of the motherboard. In such cases, a riser card may be used. A riser card is a circuit board that plugs into an expansion slot of the motherboard perpendicularly, allowing additional expansion cards to be plugged into expansion slots of the riser card in an orientation that is parallel to the motherboard, thus saving space within the case housing the components of the computing device. Thus the riser card serves as a connector or an adapter, allowing the expansion cards to electrically connect to the motherboard.

However, in order to install the expansion cards into the expansion slots or to remove the expansion cards, the case housing the components of the computing device has to be opened each time the expansion cards are installed or removed. As a result, the installation and the removal of the expansion cards tend to be laborious, cumbersome, and time-consuming. The installation and the removal techniques also tend to adversely affect the serviceability and upgradeability of the computing devices since subsequent access to the motherboard requires that the expansion cards (and the riser card, if used) be individually disconnected and removed to gain access to certain portions of the motherboard. Further, since other electronic components are also installed on the motherboard, operators may accidentally displace or damage the electronic components while connecting or disconnecting the expansion cards. When servicing or upgrading of the motherboard is completed, the removed expansion cards are then individually reconnected to the motherboard. Therefore, this disconnection and the reconnection of the expansion cards typically entail labour and are prone to errors.

In an embodiment of the present subject matter, devices and methods for engagement of an expansion card with an expansion slot of a printed circuit board (PCB) based connector are described. In one example, the expansion card may be a Peripheral Component Interconnect Express (PCIe) card.

According to an example, a computing device, such as a desktop computer, a server, and a workstation may comprise a processing unit. The processing unit may include components, for example, processors, memory chips, peripheral interface devices. PCB based connectors, and other circuit elements of the computing device. To hold the components of the processing unit together and safe, an outer housing is provided. The outer housing is an enclosure on which the components of the processing unit are mounted. In one example, the outer housing may mount a PCB based connector on its bottom wall or on its side wall.

In one example, the PCB based connector may be a motherboard having at least one expansion slot for receiving an expansion card. In another example, the PCB based connector may be a riser card having at least one expansion slot for receiving the expansion card. The riser card may be detachably coupled to the motherboard to electrically connect the motherboard with the expansion card. In case the PCB based connector is the riser card, the riser card is coupled to the wall of the outer housing through the motherboard.

According to the present subject matter, the expansion card can be inserted into the PCB based connector or removed from the PCB based connector without removing the outer housing onto which the PCB based connector is mounted. In one example, the outer housing has a number of slots, hereinafter referred to as housing slots for receiving an expansion card. Further, to engage the expansion card with an expansion slot of the PCB based connector, an expansion card module is provided. The expansion card module houses the expansion card to be plugged into the expansion slot of the PCB based connector. In operation, to engage the expansion card with the expansion slot of the PCB based connector, the expansion card module is inserted into the outer housing through a housing slot.

In one example, the expansion card module is inserted along a first axis. In said example, the first axis is along a notional central axis of the housing slot. Subsequently, a motion is provided to the expansion card module towards the PCB based connector for engagement of the expansion card with the expansion slot. In one example, the motion to the expansion card module is provided along a second axis for engaging the expansion card with the expansion slot. In said example, the second axis is perpendicular to the first axis. Similarly, the expansion card can be unplugged from the expansion slot.

In one example, to provide the motion to the expansion card module along the second axis, the outer housing is provided with a spring actuator. In another example, to provide the motion to the expansion card module along the second axis, the expansion card module is provided with a module mounted actuator for actuating the expansion card module to engage the expansion card with the expansion slot.

With the two axes motion based insertion and removal of the expansion card module and the outer housing as described above, the expansion card can be accurately and easily plugged into the expansion slot of the PCB based connector and unplugged from the expansion slot without removing the outer housing. Further, the configuration and operation of the expansion card module and the outer housing ensures that components mounted on the PCB based connector do not get damaged. Therefore, the expansion card module and the outer housing described herein provides for effective, easy, and safe insertion and removal of the expansion card, without causing any damage to the PCB based connector.

The above devices and the methods for insertion of the expansion card into the expansion slot of the PCB based connector and removal of the expansion card from the expansion slot are further described in conjunction with the following figures. It should be noted that the description and figures merely illustrate the principles of the present subject matter. Further, various arrangements may be devised that, although not explicitly described or shown herein, embody the principles of the present subject matter and are included within its spirit and scope.

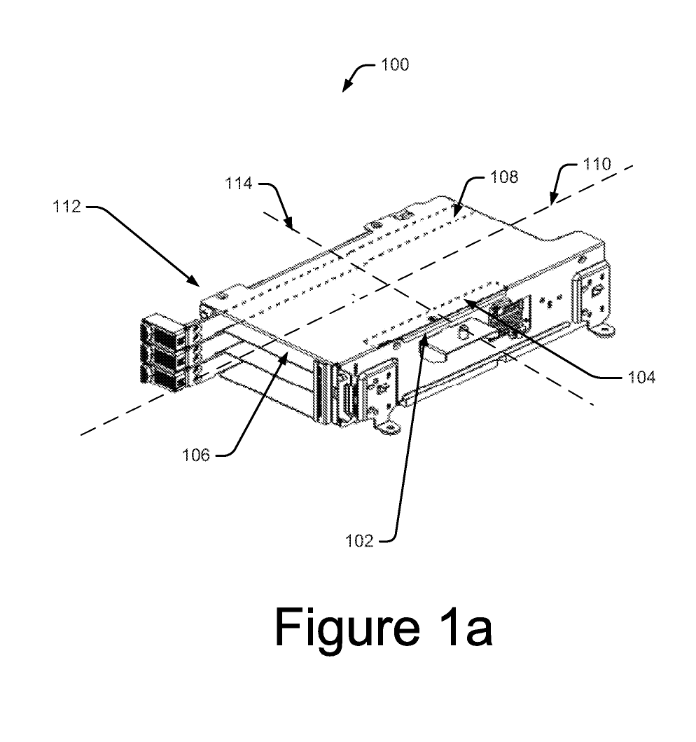

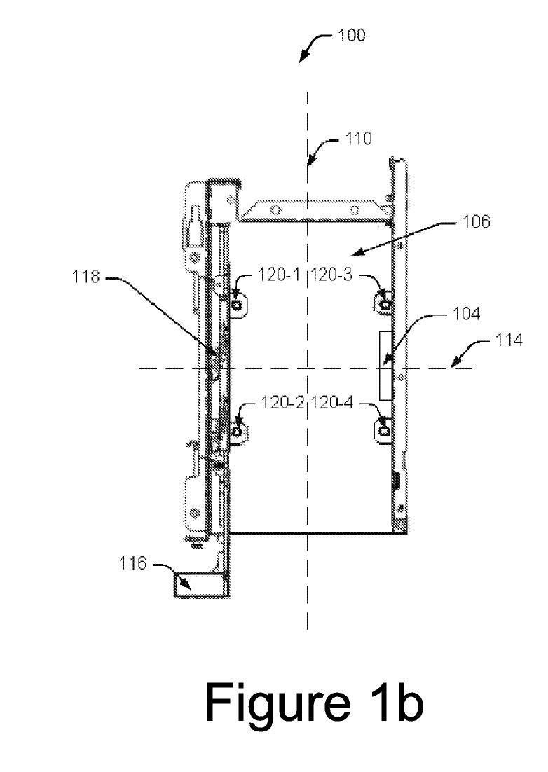

The manner in which the devices and methods for insertion of the expansion card into the expansion slot of the PCB based connector and removal of the expansion card from the expansion slot are explained in detail with respect to FIGS. 1a to 7e. While aspects of described devices and methods for insertion of the expansion card into the expansion slot and removal of the expansion card from the expansion slot can be implemented in any number of different computing systems, environments, and/or implementations, the examples and implementations are described in the context of the following device(s).

FIG. 1a illustrates a perspective view of a housing case 100 for a printed circuit board (PCB) based connector 102, according to an example of the present subject matter.

The housing case 100 is an enclosure for components of a computing device. According to one example, the computing device may be a desktop computer, a server, a workstation, and the like. The computing device may include the PCB based connector 102 located within the housing case 100. Further, in one example, the PCB based connector 102 may be mounted on a bottom wall of the housing case 100. In another example, the PCB based connector 102 may be mounted on either of two vertical opposite side walls of the housing case 100. The side walls may include a first wall and a second wall. As shown in FIG. 1a, the PCB based connector 102 is mounted on a side wall of the housing case 100.

Further, the PCB based connector 102 includes at least one expansion slot 104 for receiving an expansion card. The expansion card is plugged into the expansion slot 104 in an orientation that is perpendicular to the PCB based connector 102. In one example, the PCB based connector 102 may be a motherboard. In another example, the PCB based connector 102 may be a riser card. The riser card may be detachably coupled to the motherboard to electrically connect the motherboard with the expansion card.

The expansion card may be any function-adding card, for example, a special Peripheral Component Interconnect Express (PCIe) card, a low profile PCIe card, a standard PCIe card, a PCIe solid state drives (SSD) card, and a Small Computer System Interface (SCSI) over PCIe (SOP) SSD card.

According to one example, the housing case 100 includes at least one receiving slot 106 for receiving the expansion card. The receiving slot 106 of the housing case 100 has a side wall 108 that extends vertically downwards. The dotted parallel lines shown in FIG. 1a illustrate the side wall 108 of the receiving slot 106. As will be understood, the side wall 108 of the receiving slot 106 is formed by the second side wall of the housing case 100, such that the expansion slot 104 of the PCB based connector 102 is perpendicular to the side wall 108. In one example, the expansion slot 104 of the PCB based connector 102 and the receiving slot 106 of the housing case 100 may be configured to removably receive the expansion card.

Further, in one instance, the housing case 100 may receive an expansion card module carrying the expansion card in the receiving slot 106 along a first axis 110, where the first axis 110 is along a notional central axis of the receiving slot 106. The receiving slot 106 includes a latch assembly 112 connected to an inner side of the side wall 108 of the receiving slot 106. In one example, the latch assembly 112 includes a latch and a spring actuator connected to the latch (shown in FIG. 1b).

The latch assembly 112 provides motion to the expansion card module along a second axis 114 for engaging the expansion card with the expansion slot 104. In one example, the first axis 110 is perpendicular to the second axis 114. Therefore, when the receiving slot 106 receives the expansion card module along the first axis 110, the latch assembly 112 is actuated for providing motion to the expansion card module towards the PCB based connector 102, along the second axis 114, for engaging the expansion card with the expansion slot 104 of the PCB based connector 102.

Although, it has been depicted in FIG. 1a that the housing case 100 houses the PCB based connector 102 that has single expansion slot 104, the PCB based connector 102 having multiple expansion slots 104 may also be housed by the housing case 100.

With the two axes motion based insertion of the expansion card into the expansion slot 104 of the PCB based connector 102 mounted within the housing case 100 described above, the expansion card can be accurately and easily plugged into the expansion slot 104 of the PCB based connector 102 without having to remove the housing case 100 of the computing device.

FIG. 1b illustrates an inner top view of the housing case 100 for the PCB based connector, according to an example of the present subject matter.

The housing case 100 forms the supporting frame on which the PCB based connector of the computing device is mounted. In one example, the PCB based connector includes an expansion slot 104. The housing case 100 may also mount other components of the computing device, such as processor(s), volatile memory (RAM), mass storage devices, CD and/or DVD-drives, interface adapters, power supply and/or batteries etc (not shown in FIG. 1b).

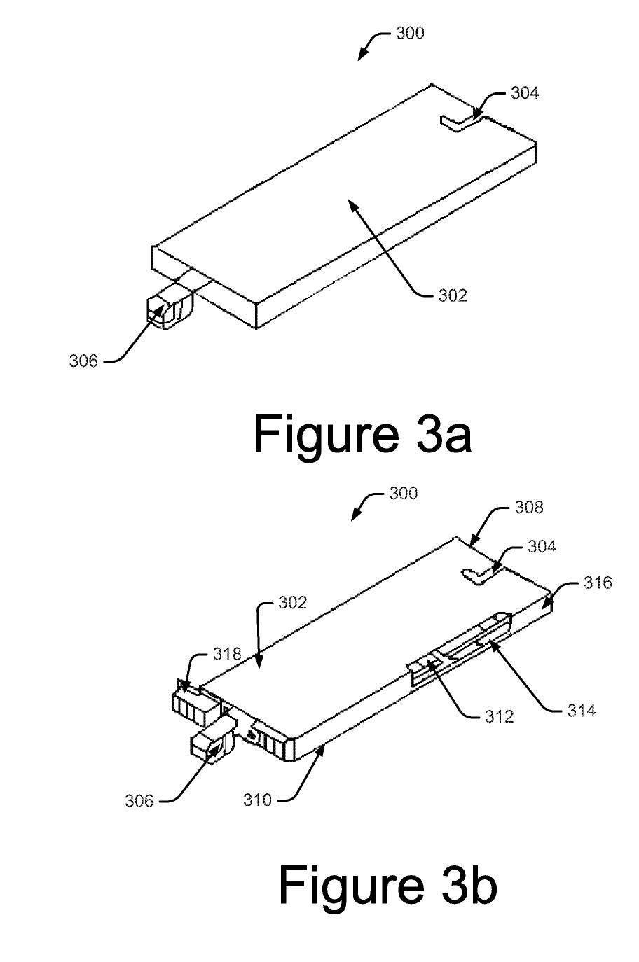

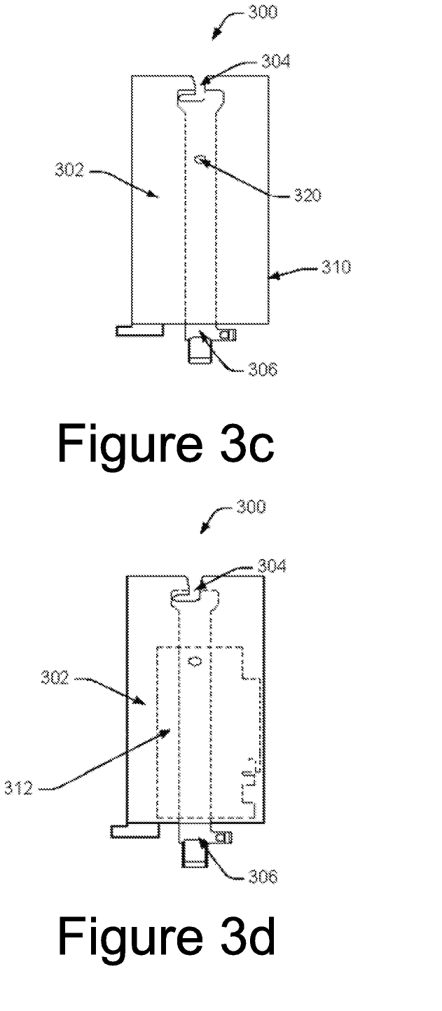

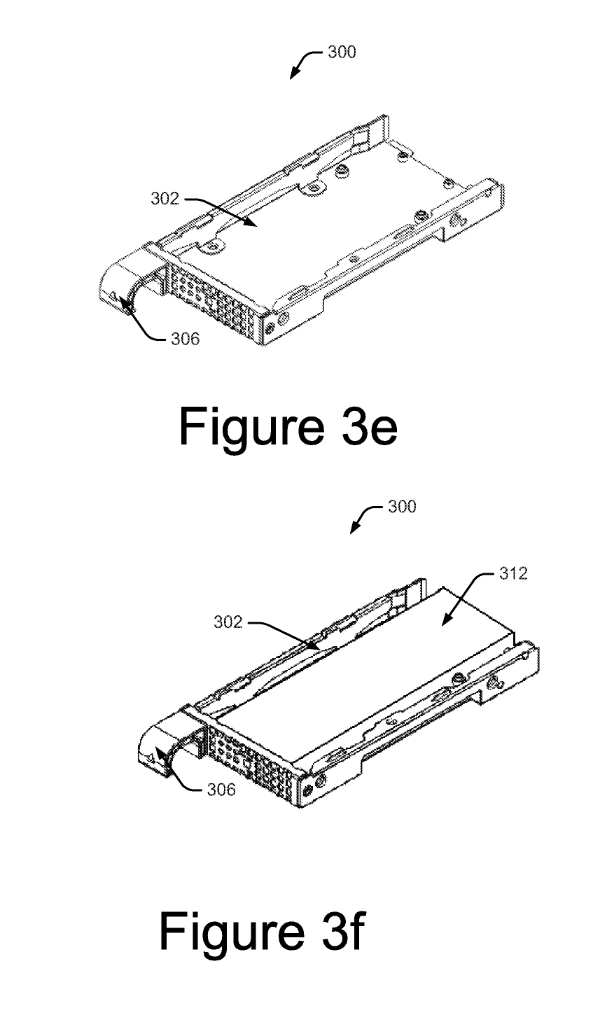

As shown in FIG. 1b, the housing case 100 includes the receiving slot 106 for receiving the expansion card module carrying the expansion card (shown in FIG. 3a) along the first axis 110. In one example, the receiving slot 106 may receive the expansion card module for engagement of the expansion card with the expansion slot 104 of the PCB based connector.

The receiving slot 106 further includes a latch 116 and a spring actuator 118 connected to the latch 116. The latch 116 actuates the spring actuator 118 for providing motion to the expansion card module towards the expansion slot 104 of the PCB based connector. During operation, after the expansion card module is inserted into the receiving slot 106 along the first axis 110, the latch 116 is pressed in the direction of the first axis 110 to actuate the spring actuator 118. Upon being actuated, the spring actuator 118 provides a motion to the expansion card module along the second axis 114 for engaging the expansion card with the expansion slot 104.

In one example, the spring actuator 118 may comprise springs, such that when the latch 116 is pressed, the springs of the spring actuator 118 pushes the expansion card module towards the expansion slot 104. As a result, the expansion card is plugged into the expansion slot 104. In one example, the latch 116 of the housing case 100 can lock the expansion card module inside the receiving slot 106. According to said example, the latch 116 is pushed along the second axis 114, i.e., towards the expansion slot 104 to lock the expansion card module inside the receiving slot 106, thereby fixing the expansion card module to avoid any the movement of the expansion card module.

According to one example, the receiving slot 106 further comprises a plurality of positioning pins 120-1, 120-2, 120-3, and 120-4, collectively referred to as positioning pins 120 and individually referred to as a positioning pin 120. The positioning pins 120 are provided for positioning the expansion card module in the receiving slot 106. Further, to unlock the expansion card module, the latch 116 is pushed away from the expansion slot 104 in the direction of the second axis 114 and the expansion card module can then be pulled out from the housing case 100.

This arrangement enables insertion of the expansion card into the expansion slot 104 of the PCB based connector and removal of the expansion card from the expansion slot 104 without having to remove the housing case 100.

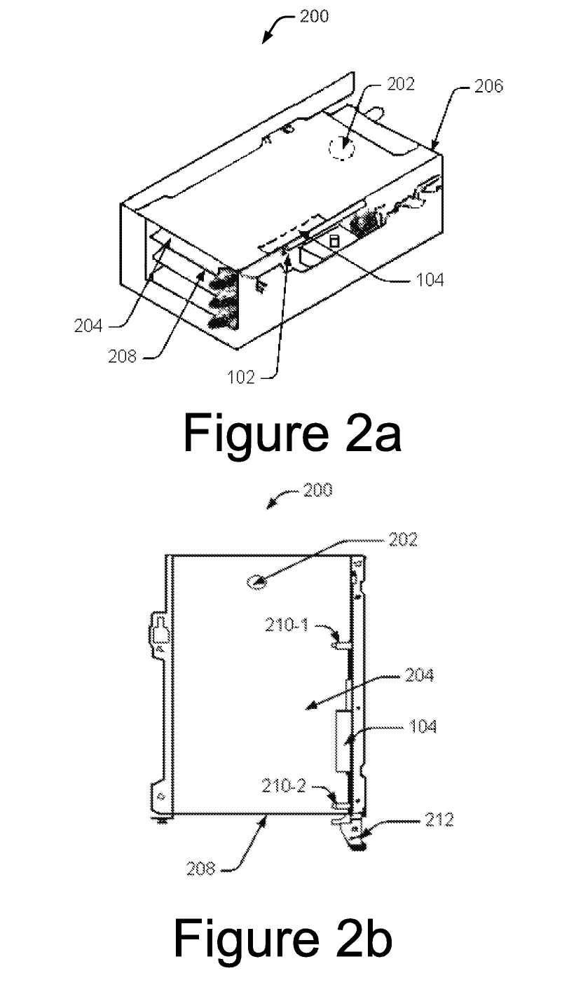

FIG. 2a illustrates a perspective view of a device case housing 200 for the PCB based connector 102, according to an example of the present subject matter.

In one example, the device case housing 200 is similar to the housing case 100. The difference between the device case housing 200 and the housing case 100 is that the device case housing 200 does not include the latch assembly 112. Instead, the device case housing includes a locking element 202 to mount the expansion card module in the device case housing 200.

The device case housing 200 is an enclosure for the components of the computing device on which the PCB based connector 102 is mounted. The PCB based connector 102 includes at least one expansion slot 104 for receiving the expansion card. In one example, the PCB based connector 102 may be mounted on a bottom wall of the device case housing 200. In another example, the PCB based connector 102 may be mounted on a side wall of the device case housing 200. As shown in FIG. 2a, the PCB based connector 102 is mounted on the side wall of the device case housing 200.

According to one example, the device case housing 200 includes at least one module slot 204 for receiving the expansion card module carrying the expansion card to he engaged with the expansion slot 104 of the PCB based connector 102. In one example, the expansion slot 104 of the PCB based connector 102 and the module slot 204 of the device case housing 200 may be configured to removably receive the expansion card.

Further, the module slot 204 includes the locking element 202 to mount the expansion card module in the device case housing 200. The dotted circle shown in FIG. 2a illustrates the locking element 202. In one example, the locking element 202 may be provided on one of an upper wall 206 of the module slot 204 and a lower wall 208 of the module slot 204, parallel to the upper wall 206. In one example, the locking element 202 actuates the expansion card module for engagement of the expansion card with the expansion slot 104.

Although, it has been depicted in FIG. 2a that the device case housing 200 houses the PCB based connector 102 that has single expansion slot 104, the PCB based connector 102 having multiple expansion slots 104 may also be housed by the device case housing 200.

FIG. 2b illustrates an inner top view of the device case housing 200 for the PCB based connector, according to an example of the present subject matter.

The device case housing 200 forms a supporting frame on which the PCB based connector of the computing device is mounted. In one example, the PCB based connector includes the expansion slot 104. The device case housing 200 may also mount other components of the computing device, such as processor(s), volatile memory (RAM), mass storage devices, CD and/or DVD-drives, interface adapters, power supply and/or batteries etc (riot shown in FIG. 2b).

As shown in FIG. 2b, the device case housing 200 includes the module slot 204 for receiving the expansion card module carrying the expansion card. In one example, the module slot 204 receives the expansion card module for engagement of the expansion card with the expansion slot 104 of the PCB based connector.

The module slot 204 further includes the locking element 202. As shown in FIG. 2b, the locking element 202 is present on the lower wall 208 of the module slot 204. Although, it is shown that the locking element 202 is present on the lower wall 208 of the module slot 204, the locking element 202 can also be present on the upper wall of the module slot 204. In one example, the locking element 202 mounts the expansion card module and actuates the expansion card module for engagement of the expansion card with the expansion slot 104.

Further, the module slot 204 includes a first side wall and a second side wall extending vertically downwards, such that the first side wall and the second side wall are perpendicular to the expansion slot 104 of the PCB based connector (not shown in FIG. 2b). The module slot 204 also comprises guiding pins 210-1 and 210-2, collectively referred to as guiding pins 210 and individually referred to as a guiding pin 210 for guiding the expansion card module, during insertion, into the module slot 204. In one example, the guiding pins 210 are attached to the first side wall of the module slot 204. In another example, the guiding pins 210 are attached to the second side wall of the module slot 204. In yet another example, the guiding pins 210 are attached to both the first side wall and the second side wall of the module slot 204, Although, it is shown that two guiding pins 210-1 and 210-2 are attached to the side wall of the module slot 204, more than two guiding pins 210 can be attached to the side wall.

In one example, the device case housing 200 also comprises a clip 212 to lock the expansion card module inside the module slot 204, thereby fixing the expansion card module to avoid any the movement of the expansion card module. Further, to unlock and remove the expansion card module from the device case housing 200, the clip 212 is pushed vertically downwards to unlock the expansion card module from the device case housing 200 for release.

According to the present subject matter, the expansion card can be inserted into the expansion slot 104 of the PCB based connector or can be removed from the expansion slot 104 without removing the device case housing 200 onto which the PCB based connector is mounted.

FIG. 3a illustrates a perspective view of the expansion card module 300 for engagement of the expansion card with the PCB based connector, according to an example of the present subject matter.

In one example, the expansion card module 300 carries the expansion card to be inserted into the expansion slot of the PCB based connector. As shown in FIG. 3a, the expansion card module 300 includes a card housing 302 to house the expansion card within it. According to an example, the card housing 302 further includes a groove 304 for engaging the card housing 302 with the locking element of the device case housing to mount the expansion card module 300 in the device case housing. The expansion card module 300 further includes a module mounted actuator 306 pivotally mounted on the card housing 302 to engage with the locking element of the device case housing for actuating the expansion card module 300 to engage the expansion card with the expansion slot of the PCB based connector.

According to an example, the module mounted actuator 306 provides motion to the expansion card module 300 towards the PCB based connector for engagement of the expansion card with the expansion slot of the PCB based connector. The module mounted actuator 306 of the expansion card module 300 allows an operator to grip the expansion card module 300 while operating the expansion card module 300.

FIG. 3b illustrates a perspective view of the expansion card module 300 housing the expansion card 312, according to an example of the present subject matter.

As shown in FIG. 3b, the expansion card module 300 includes the card housing 302 which houses the expansion card 312. In one example, the card housing 302 includes a first wall 308 and a second wall 310, such that the first wall 308 is parallel to the second wall 310. The card housing 302 also includes a side wall 316 extending vertically downwards, such that the first wall 308 and the second wall 310 perpendicularly attached to either side of the side wall 316. Further, the card housing 302 includes the groove 304. As shown in FIG. 3b, the groove 304 of the card housing 302 is on the first wall 308. Although, in the illustrated example the groove 304 is on the first wall 308 of the card housing 302, the groove 304 may be on the second wall 310 of the card housing in various other examples.

In one example, the expansion card module 300 also includes a the module mounted actuator 306 pivotally mounted on the card housing 302 for actuating the expansion card module 300 to engage the expansion card 312 with an expansion slot of a PCB based connector. Further, the card housing 302 has an opening 314 on the side wall 316 for protrusion of a portion of the expansion card 312 for engaging the expansion card 312 with the expansion slot of the PCB based connector. The expansion card module 300 also includes a visual indicator 318. In one example, the visual indicator 318 may be Light Emitting Diodes (LEDs). The visual indicator 318 provides for monitoring insertion of the expansion card module 300 into the housing case 100 or into the device case housing 200. The visual indicator 318 also provides for monitoring removal of the expansion card module 300 from the housing case 100 or from the device case housing 200. In one example, the visual indicator 318 may glow when the expansion card module 300 is inserted correctly into the device case housing 200 and turns off when the expansion card module 300 is removed.

According to one example, the expansion card module 300 is a hot-pluggable module. That means, the expansion card 312 can be plugged into the expansion slot of the PCB based connector or can be unplugged from the expansion slot while the computing device's main power is on.

FIG. 3c illustrates an inner top view of the expansion card module 300, according to an example of the present subject matter.

As shown in FIG. 3c, the expansion card module 300 includes the card housing 302. Further, the card housing 302 includes the groove 304 on its second wall 310. Further, the expansion card module 300 includes the module mounted actuator 306 pivotally mounted on the card housing 302. In one example, the module mounted actuator 306 is mounted on the card housing by a screw 320.

FIG. 3d illustrates an inner top view of the expansion card module 300 having the expansion card 312, according to an example of the present subject matter.

As shown in FIG. 3d, the expansion card module 300 includes the card housing 302 housing the expansion card 312. Further, the groove 304 of the card housing 302 and the module mounted actuator 306 are aligned with each other to engage with the locking element of the device case housing for actuating the expansion card module 300 to engage the expansion card 312 with the expansion slot of the PCB based connector.

FIGS. 3e and 3f illustrate the expansion card module 300, according to another example of the present subject matter.

As shown in FIGS. 3e and 3f, the expansion card module 300 of different shape can be implemented for engagement of the expansion card 312 with the expansion slot of the PCB based connector.

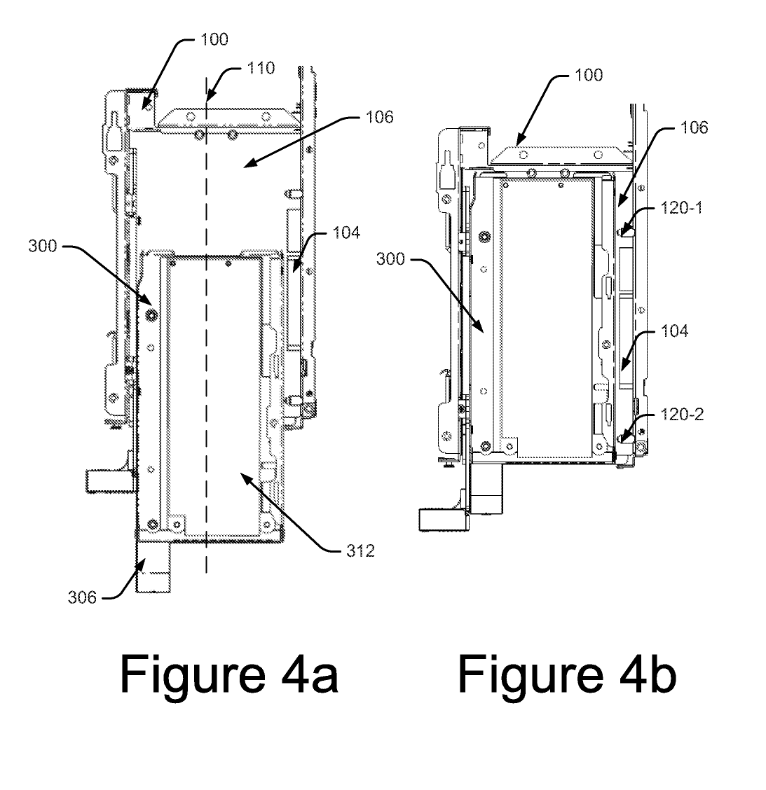

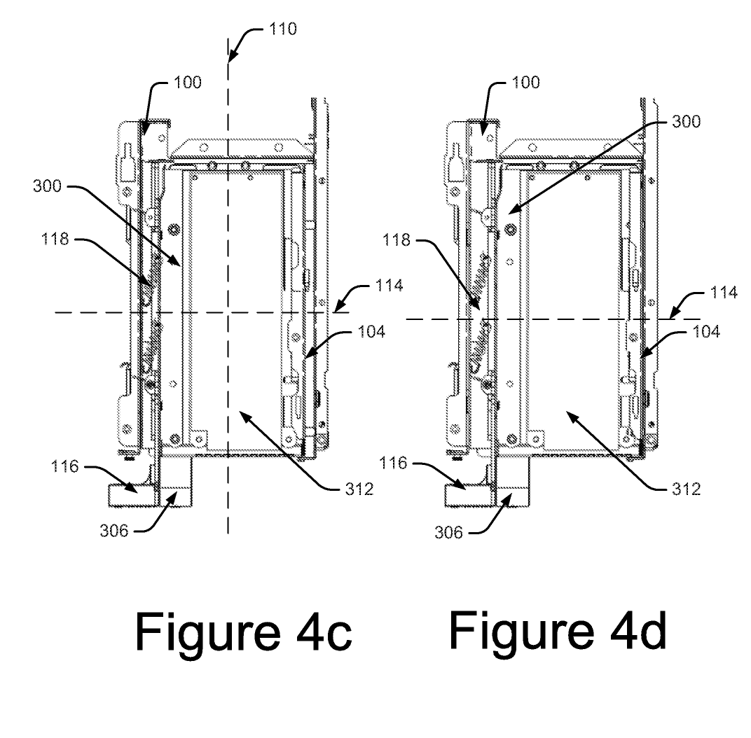

FIGS. 4a 4b, 4c, and 4d illustrate the expansion card module 300 inserted into the housing case 100 for engagement of the expansion card 312 with the expansion slot 104 of the PCB based connector, according to an example of the present subject matter.

FIG. 4a illustrates the expansion card module 300 while being inserted inside into the housing case 100. As illustrated, the expansion card module 300 having the expansion card 312 is inserted inside the receiving slot 106 of the housing case 100 along the first axis 110. According to an example, the module mounted actuator 306 of the expansion card module 300 allows an operator to grip the expansion card module 300 while operating the expansion card module 300.

FIG. 4b illustrates the expansion card module 300 placed in the receiving slot 106 of the housing case 100. In one example, the positioning pins 120-1 and 120-2 facilitate proper positioning of the expansion card module 300 in the receiving slot 106 of the housing case 100.

FIG. 4c illustrates the expansion card 312 inserted into the expansion slot 104 of the PCB based connector mounted on the housing case 100. As illustrated, the latch 116 of the housing case 100 is pushed in the direction of the first axis 110. Consequently, the latch 116 actuates the spring actuator 118 of the housing case 100. The spring actuator 118 provides motion to the expansion card module 300 along the second axis 114, i.e., towards the expansion slot 104 for engagement of the expansion card 312 with the expansion slot 104.

FIG. 4d illustrates the expansion card 312 placed in the expansion slot 104 of the PCB based connector. Once the expansion card 312 is plugged into the expansion slot 104, the latch 116 of the housing case 100 is pushed along the second axis 114 to lock the expansion card module 300 inside the receiving slot 106, thereby fixing the expansion card module 300 to avoid any the movement of the expansion card module 300. In one example, the module mounted actuator 306 of the expansion card module 300 is locked to the latch 116 of the housing case 100.

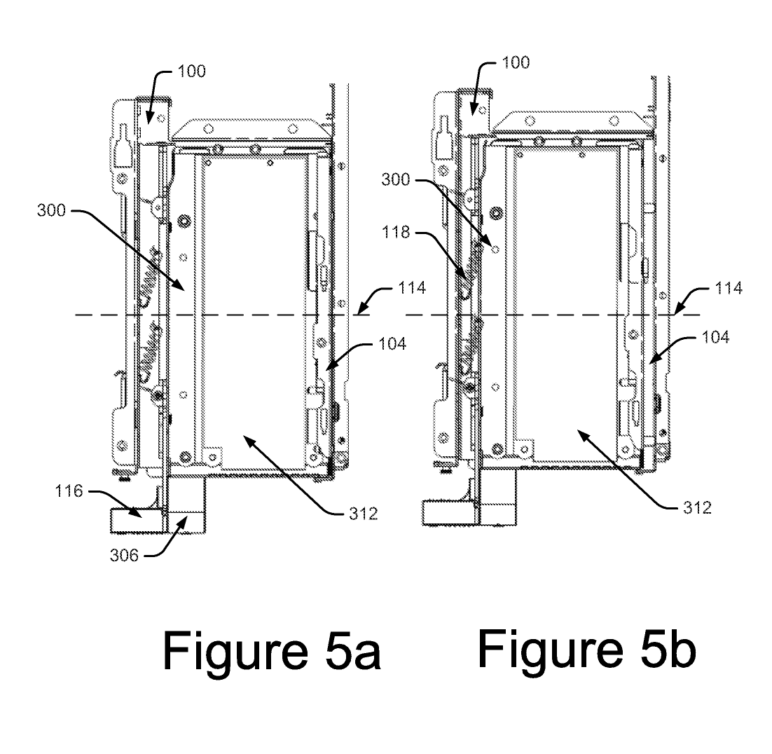

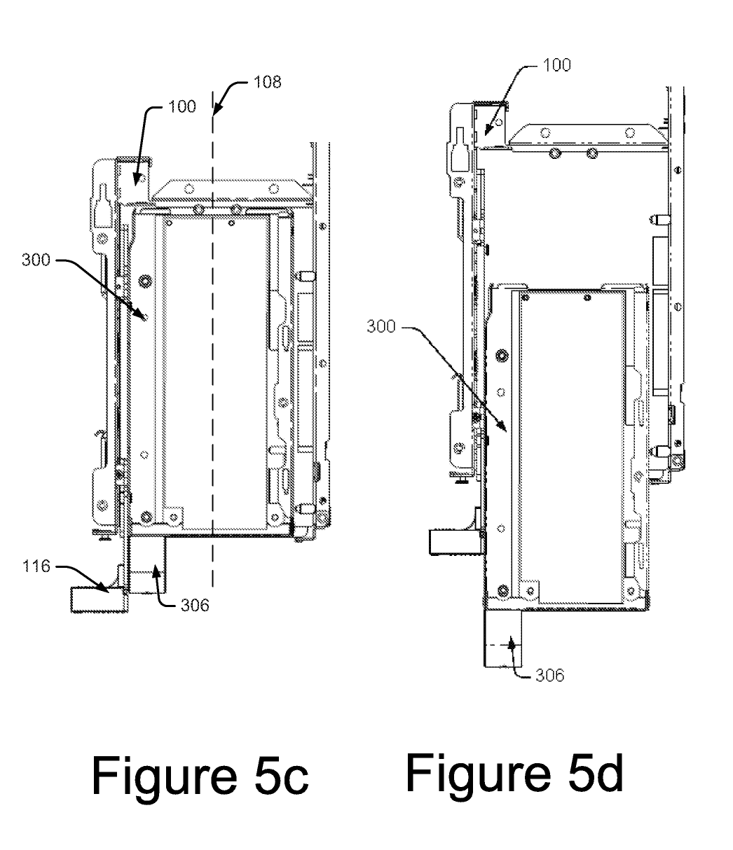

FIGS. 5a 5b, 5c, and 5d illustrate the expansion card module 300 removed from the housing case 100 for disengagement of the expansion card 312 from the expansion slot 104 of the PCB based connector, according to an example of the present subject matter.

FIG. 5a illustrates the expansion card 312 while being removed from the expansion slot 104. In one example, the latch 116 of the housing case 100 is pushed along the direction of the second axis 114, i.e., away from the expansion slot 104 to unlock the expansion card module 300.

FIG. 5b illustrates the expansion card 312 after being unplugged from the expansion slot 104. As shown in FIG. 5b, the expansion card 312 is unplugged from the expansion slot 104 and the expansion card module 300 is now away from the expansion slot 104. In other words, the expansion card module 300 has moved towards the spring actuator 118 of the housing case 100 along the direction of the second axis 114.

FIG. 5c illustrates the expansion card module 300 being unlocked from the latch 116. The latch 116 of the housing case 100 is pulled along the direction of the first axis 110. Consequently, the module mounted actuator 306 of the expansion card module 300 is unlocked from the latch 116.

FIG. 5d illustrates the expansion card module 300 being removed from the housing case 100. Once the module mounted actuator 306 gets unlocked, the expansion card module 300 is pulled out from the housing case 100. According to one example, the operator may pull the module mounted actuator 306 to release the expansion card module 300 from the housing case 100.

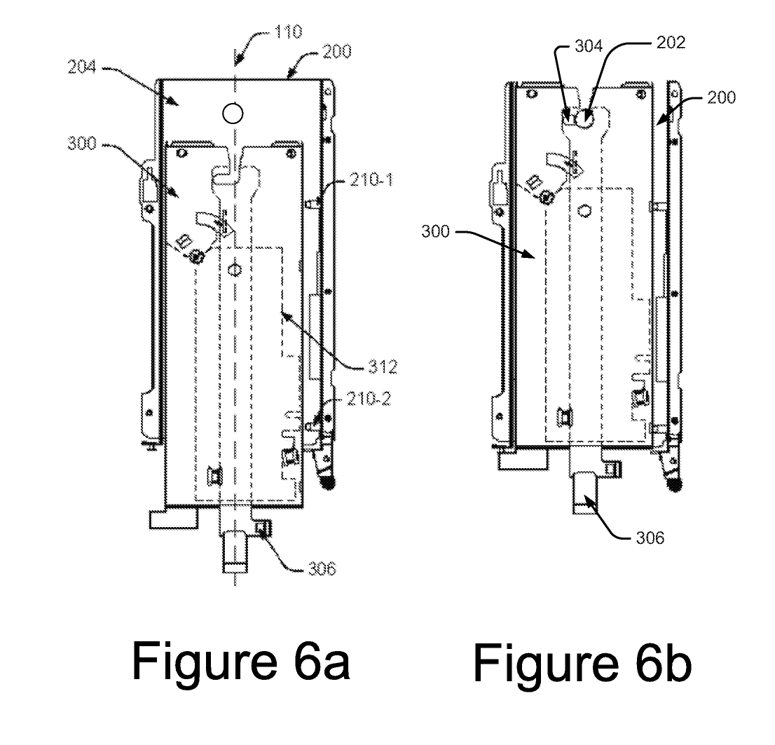

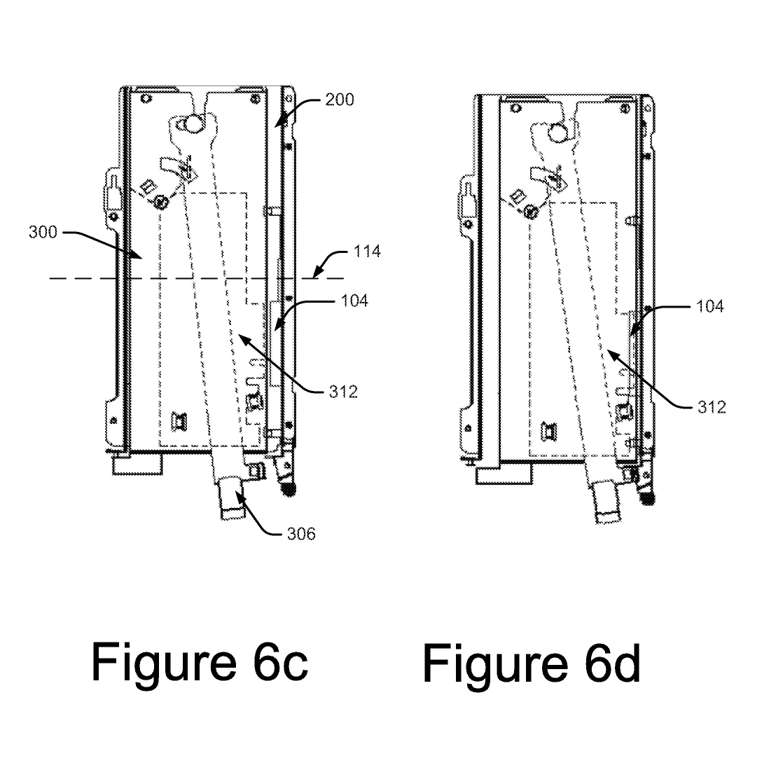

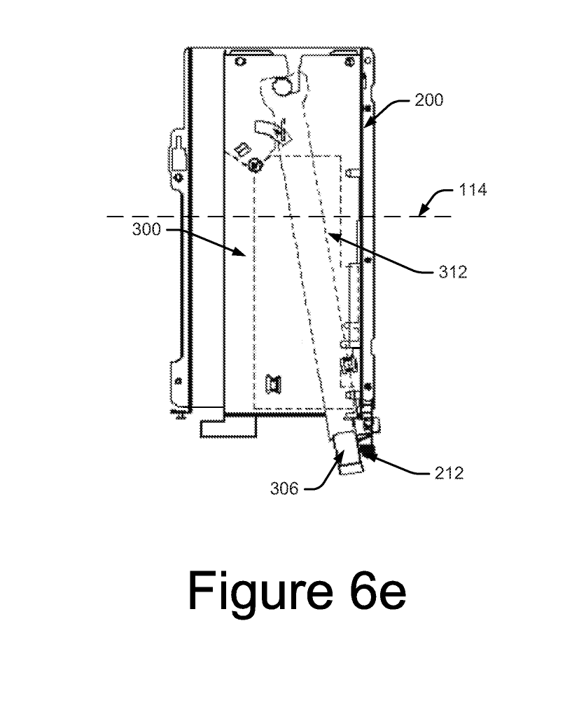

FIGS. 6a, 6b, 6c, 6d, and 6e illustrate the expansion card module 300 inserted into the device case housing 200 for engagement of the expansion card 312 with the expansion slot 104 of the PCB based connector, according to an example of the present subject matter.

FIG. 6a illustrates the expansion card module 300 while being inserted inside into the device case housing 200. As illustrated, the expansion card module 300 having the expansion card 312 is inserted inside the module slot 204 of the device case housing 200 along the first axis 110. According to an example, the module mounted actuator 306 of the expansion card module 300 allows the operator to grip the expansion card module 300 to insert the expansion card module 300 in the module slot 204. In one example, the guiding pins 210-1 and 210-2 guide the expansion card module 300 inside the module slot 204 during insertion.

FIG. 6b illustrates the expansion card module 300 engaged with the device case housing 200. While the expansion card module 300 is inserted in the module slot 204 of the device case housing 200, the groove 304 and the module mounted actuator 306 of the expansion card module 300 engage with the locking element 202 of the device case housing 200 to mount the expansion card module 300 in the device case housing 200.

FIG. 6c illustrates the expansion card 312 while being inserted into the expansion slot 104 of the PCB based connector mounted on the device case housing 200. The module mounted actuator 306 of the expansion card module 300 is pushed towards the expansion slot 104 along the second axis 114 for actuating the expansion card module 300 for engagement of the expansion card 312 with the expansion slot 104. Once the expansion card 312 is coupled to the expansion slot 104, the module mounted actuator 306 will remain there until the expansion card 312 is removed from the expansion slot 104.

FIG. 6d illustrates the expansion card 312 placed securely in the expansion slot 104 of the PCB based connector.

FIG. 6e illustrates the expansion card module 300 fixed to the device case housing 200. Once the expansion card 312 is plugged into the expansion slot 104, the module mounted actuator 306 is pushed towards the expansion slot 104 along the second axis 114 to lock itself with the clip 212 of the device case housing 200, thereby fixing the expansion card module 300 inside the device case housing 200 to avoid any the movement of the expansion card module 300.

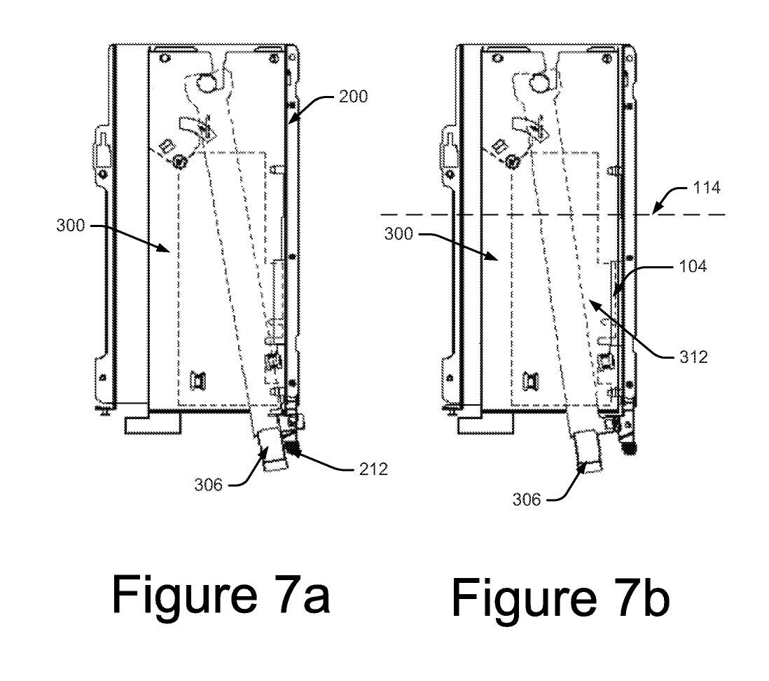

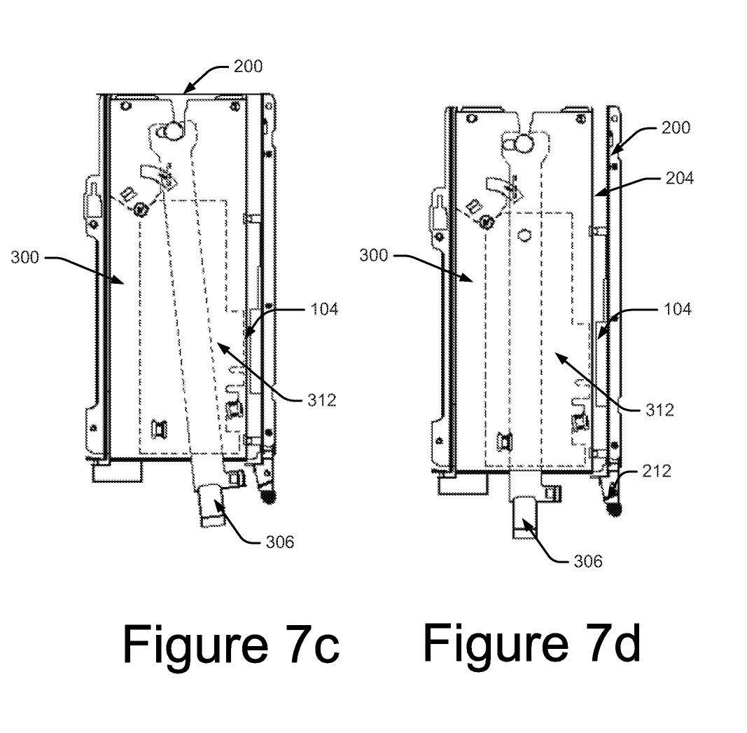

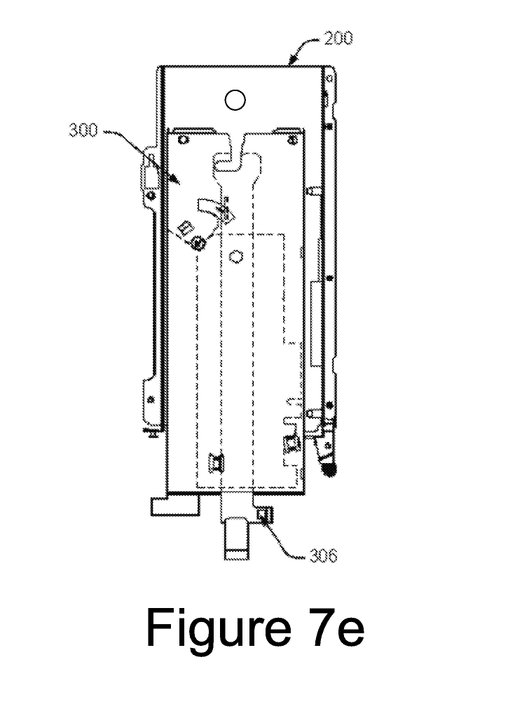

FIGS. 7a, 7b, 7c, 7d, and 7e illustrate the expansion card module 300 removed from the device case housing 200 for disengagement of the expansion card 312 from the expansion slot 104 of the PCB based connector, according to an example of the present subject matter.

FIG. 7a illustrates the expansion card module 300 for being removed from the device case housing 200. The clip 212 of the device case housing 200 is pushed vertically downwards to unlock the expansion card module 300 from the device case housing 200 for release.

FIGS. 7b, 7c, and 7d illustrate the expansion card 312 while being removed from the expansion slot 104. In one example, the module mounted actuator 306 of the expansion card module 300 is pushed away from the expansion slot 104 along the direction of the second axis 114, to unplug the expansion card 312 from the expansion slot 104. In one example, the module mounted actuator 306 of the expansion card module 300 is pushed away from the expansion slot 104 till the notional central axis of the module slot 204 of the device case housing 200. As shown in FIG. 7d, the expansion card 312 is unplugged from the expansion slot 104 and the expansion card module 300 is at the notional central axis of the module slot 204.

FIG. 7e illustrates the expansion card module 300 being removed from the device case housing 200. Once the expansion card module 300 is at the notional central axis, the expansion card module 300 is pulled out from the device case housing 200. According to one example, the operator may pull the module mounted actuator 306 to release the expansion card module 300 from the device case housing 200.

Although implementations for engagement of an expansion card with an expansion slot of a PCB based connector have been described in language specific to structural features and/or methods, it is to be understood that the appended claims are not necessarily limited to the specific features or methods described. Rather, the specific features and methods are disclosed as examples of devices and methods for engagement of the expansion card with the expansion slot of the PCB based connector.

We claim:

1. A housing case (100) for housing a printed circuit board (PCB) based connector (102), wherein the PCB based connector (102) has at least one expansion slot (104) for receiving an expansion card (312), the housing case (100) comprising:
at least one receiving slot (106) for receiving the expansion card (312) along a first axis (110), wherein the at least one receiving slot (106) comprises:
a side wall (108) extending vertically downwards;
a latch assembly (112) connected to the side wall (108) of the at least one receiving slot (106) for:
providing motion to the expansion card (312) along a second axis (114); and
engaging the expansion card (312) with the at least one expansion slot (104),
wherein the first axis (110) is along a notional central axis of the at least one receiving slot (106), and wherein the first axis (110) is perpendicular to the second axis (114).

2. The housing case (100) as claimed in claim 1, wherein the latch assembly (112) comprises a latch (116) for actuating a spring actuator (118) connected to the latch (116), and wherein the spring actuator (118) provides motion to the expansion card (312) in the at least one receiving slot (106) towards the PCB based connector (102), along the second axis (114), for engagement in the at least one expansion slot (104) of the PCB based connector (102).

3. The housing case (100) as claimed in claim 1, wherein the at least one receiving slot (106) further comprises a plurality of positioning pins (120) for positioning the expansion card (312) in the at least one receiving slot (106).

4. The housing case (100) as claimed in claim 1, wherein the PCB based connector (102) is a riser card, and wherein the PCB based connector (102) is detachably coupled to a motherboard to connect the motherboard with the expansion card (312). The housing case (100) as claimed in claim 1, wherein the PCB based connector (102) is a motherboard.

6. A device case housing (200) for housing a PCB based connector (102), wherein the PCB based connector (102) has at least one expansion slot (104) for receiving an expansion card (312), the device case housing (200) comprising:
at least one module slot (204) for receiving an expansion card module (300), wherein the at least one module slot (204) comprises:
a locking element (202) to mount the expansion card module (300) in the device case housing (200), wherein the locking element (202) actuates the expansion card module (300) to engage the expansion card (312) with the at least one expansion slot (104), and wherein
the locking element (202) is provided on one of an upper wall (206) of the at least one module slot (204) and a lower wall (208) of the at least one module slot (204), and wherein the upper wall (206) is parallel to the lower wall (208).

7. The device case housing (200) as claimed in claim 6, wherein the at least one module slot (204) comprises:
a first side wall and a second side wall extending vertically downwards, wherein the first side wall and the second side wall are perpendicular to the at least one expansion slot (104) of the PCB based connector (102); and
a plurality of guiding pins (210) attached to at least one of the first side wall and the second side wall for guiding the expansion card module (300) for insertion into the at least one module slot (204).

8. The device case housing (200) as claimed in claim 6, wherein the device case housing (200) further comprises a clip (212) to lock the expansion card module (300) in the at least one module slot (204).

9. An expansion card module (300) for a PCB based connector (102), wherein the PCB based connector (102) has at least one expansion slot (104) for receiving an expansion card (312), the expansion card module (300) comprising:
a card housing (302) to house the expansion card (312), wherein the card housing (302) comprises a groove (304) for engaging the card housing (302) with a locking element (202) in a module slot (204) of a device case housing (200) to mount the expansion card module (300) in the device case housing (200); and
a module mounted actuator (306) pivotally mounted on the card housing (302) to engage with the locking element (202) of the device case housing (200) for actuating the expansion card module (300) to engage the expansion card (312) with the at least one expansion slot (104),
wherein the module mounted actuator (306) provides motion to the expansion card module (300) towards the PCB based connector (102) for engagement of the expansion card (312) with the at least one expansion slot (104) of the PCB based connector (102).

10. The expansion card module (300) as claimed in claim 9, wherein the card housing (302) has the groove (304) on one of a first wall (308) of the card housing (302) and a second wall (310) of the card housing (302), wherein the first wall (308) is parallel to the second wall (310).

11. The expansion card module (300) as claimed in claim 9, wherein Ule card housing (302) has an opening (314) on a side wall (316) for protrusion of a portion of the expansion card (312) for engagement of the expansion card (312) with the at least one expansion slot (104), and wherein the side wall (316) extends vertically downwards.

12. The expansion card module (300) as claimed in claim 9, wherein the expansion card (312) includes a special PCIe card, a low profile PCIe card, and a standard PCIe card.

13. The expansion card module (300) as claimed in claim 9, wherein the groove (304) of the card housing (302) and the module mounted actuator (306) are aligned with each other to engage with the locking element (202) of the device case housing (200) for actuating the expansion card module (300) to engage the expansion card (312) with the at least one expansion slot (104).

14. The expansion card module (300) as claimed in claim 9 further comprises a visual indicator (318) for monitoring insertion of the expansion card module (300) into the device case housing (200).

15. The expansion card module (300) as claimed in claim 14, wherein the visual indicator (318) further monitors removal of the expansion card module (300) from the device case housing (200).
